(19) United States
(12) Patent Application Publication
(10) Pub. No.: US 2024/0030836 A1
(43) Pub. Date: Jan. 25, 2024

(54) WATT-LEVEL PIEZOELECTRIC TRANSDUCER IN SIMPLY SUPPORTED BEAM STRUCTURE UNDER TRAFFIC LOAD AND PIEZOELECTRIC DEVICE

(71) Applicants: Peng Wang, Wenzhou (CN); Haofeng Zhang, Wenzhou (CN); Jiayao Pan, Wenzhou (CN); Jun Wang, Wenzhou (CN); Lin Guo, Wenzhou (CN); Chuan Gu, Wenzhou (CN); Xiaotian Yang, Wenzhou (CN)

(72) Inventors: Peng Wang, Wenzhou (CN); Haofeng Zhang, Wenzhou (CN); Jiayao Pan, Wenzhou (CN); Jun Wang, Wenzhou (CN); Lin Guo, Wenzhou (CN); Chuan Gu, Wenzhou (CN); Xiaotian Yang, Wenzhou (CN)

(21) Appl. No.: 17/813,586

(22) Filed: Jul. 19, 2022

(51) Int. Cl. H02N 2/18; H01L 41/113; H01L 41/187

(52) U.S. Cl. CPC H02N 2/181; H01L 41/1134; H01L 41/187

(57) ABSTRACT

Disclosed is a watt-level piezoelectric transducer in a simply supported beam structure under a traffic load. The piezoelectric transducer includes a piezoelectric transducer body, the piezoelectric transducer body including a housing, a plurality of piezoelectric beam units and an energy collection unit; each piezoelectric beam unit includes a beam support component, a plurality of piezoelectric plate components and a metal stress transmission plate, where the beam support component includes two support members; and the piezoelectric plate components sequentially penetrate the metal stress transmission plate, two ends of each of the plurality of piezoelectric plate components are transversely inserted between the two support members, and the plurality of piezoelectric plate components are arranged in a simply supported manner. The piezoelectric transducer can collect piezoelectric energy under the action of a road load, and store the energy by means of the energy collection system, so to achieve watt-level energy output.

### TECHNICAL FIELD

The present disclosure relates to research on energy output of piezoelectric ceramics under a traffic load, in particular to a watt-level piezoelectric transducer in a simply supported beam structure under a traffic load, and a piezoelectric device based on the watt-level piezoelectric transducer in a simply supported beam structure under a traffic load.

### BACKGROUND ART

Economic development of various countries is accompanied by increasing intensification of energy consumption and environmental pollution, especially the environmental problems caused by excessive emissions of carbon dioxide and other gases. At present, environmental protection and energy saving of the countries are oriented towards carbon neutrality through carbon dioxide emission reduction and green energy collection and utilization. To this end, the energy structure needs to be transformed and fossil fuels are replaced with clean energy such as renewable resources and nuclear energy.

Recently, emphasis is put on road energy collection. Pavement damage is caused due to mechanical energy and heat energy consumption produced by a large number of traffic loads, and piezoelectric energy collection technology can use piezoelectric effect to convert the consumed energy into electric energy and effectively protect the pavement. Road piezoelectric energy is gradually applied to road engineering on account of its sustainability and good adaptability. As the main apparatuses in a road piezoelectric energy collection system, piezoelectric transducers attract attention of vast researchers, but have poor output performance due to limits of piezoelectric material and coupling to external environment in the majority.

### SUMMARY

In order to solve the technical problem, the present disclosure provides a watt-level piezoelectric transducer in a simply supported beam structure under a traffic load. The piezoelectric transducer efficiently converts mechanical energy into electrical energy, and greatly improves power generation capacity and efficiency.

To this end, the present disclosure provides a watt-level piezoelectric transducer in a simply supported beam structure under a traffic load. The piezoelectric transducer includes a piezoelectric transducer body, the piezoelectric transducer body including a housing, a plurality of piezoelectric beam units and an energy collection unit, where the piezoelectric beam units and the energy collection unit are arranged in the housing, and the piezoelectric beam units are electrically connected to the energy collection unit by means of wires; each piezoelectric beam unit includes a beam support component, a plurality of piezoelectric plate components and a metal stress transmission plate, where the beam support component includes two support members oppositely arranged, the support members are in a simply supported beam structure, and the metal stress transmission plate is vertically arranged within a beam span between the two support members oppositely arranged; and the plurality of piezoelectric plate components sequentially penetrate the metal stress transmission plate, two ends of each of the plurality of piezoelectric plate components are transversely inserted between the two support members in turn, and the plurality of piezoelectric plate components are arranged in a simply supported manner.

Preferably, the housing includes an upper cover plate, a lower bottom plate and side walls, the side walls are composed of segmented side walls, and the side walls are respectively fixed on outer sides of the lower bottom plate; a bottom of the upper cover plate is provided with a rubber buffer layer, a plurality of recess groups adapted to the piezoelectric beam units are cut in the lower bottom plate, the recess group including a stress transmission plate recess and two support member recesses, and inner walls of that side walls are provided with slots which correspond to and are adapted to the support members of the piezoelectric beam units; and when the piezoelectric beam units are placed into the housing, the support members at outer sides of the piezoelectric beam units are inserted into the slots, bottoms of the support members are placed in corresponding support member recesses, and the metal stress transmission plates are placed in corresponding stress transmission plate recesses.

Preferably, the piezoelectric plate component is composed of piezoelectric ceramic and a stainless steel substrate, the piezoelectric ceramic is fixed on the stainless steel substrate, the piezoelectric ceramic and stainless steel substrate are welded on one end of the wire, and the other end of the wire is connected to the energy collection unit.

Preferably, the energy collection unit includes a rectification unit and an integrated circuit, the rectification unit is a circuit board with a rectifier bridge, the plurality of piezoelectric plate components are connected to the rectifier bridge on the circuit board by means of wires respectively, the integrated circuit is an energy management chip, and the energy management chip is connected to the circuit board by means of a wire.

Preferably, a plurality of evenly distributed bearing recesses are cut on a side wall of each support member, the bearing recesses of the two support members are oppositely provided, the two ends of each piezoelectric plate component are inserted into the bearing recesses respectively, when the two ends of each piezoelectric plate component are inserted into the bearing recesses, displacement space is left between the bearing recesses and the piezoelectric plate component, and the displacement space allows the piezoelectric plate component to move in the bearing recesses.

In the present disclosure, the piezoelectric transducer uses the simply supported beam structure, the plurality of piezoelectric plate components are arranged in a simply supported manner, and the gaps are provided between the simply supported piezoelectric plate components, such that each piezoelectric plate component has deformation space in an up-and-down direction, each piezoelectric plate component may be fully deformed by means of stress transmission of the metal stress transmission plate to generate maximum power. Compared with the traditional piezoelectric device, the piezoelectric transducer may output more power with higher efficiency. The piezoelectric transducer collects piezoelectric energy under the action of a road load, and stores the energy by means of the energy collection system, so to achieve wan-level energy output.

### BRIEF DESCRIPTION OF THE DRAWINGS

FIG. 1 is a structural schematic diagram of a watt-level piezoelectric transducer in a simply supported beam structure under a traffic load provided by a first embodiment of the present disclosure;

FIG. 2 is a schematic diagram of an exploded structure of the watt-level piezoelectric transducer in a simply supported beam structure under a traffic load in FIG. 1;

FIG. 3 is a structural schematic diagram of a piezoelectric beam unit of the watt-level piezoelectric transducer in a simply supported beam structure under a traffic load in FIG. 1;

FIG. 4 is a schematic diagram of an exploded structure of an energy collection unit of the piezoelectric beam unit of the watt-level piezoelectric transducer in a simply supported beam structure under a traffic load in FIG. 1;

FIG. 5 is a schematic diagram of a sectional structure of a watt-level piezoelectric transducer in a simply supported beam structure under a traffic load provided by a second embodiment of the present disclosure;

FIG. 6 is a schematic diagram of an exploded structure of a piezoelectric device based on the watt-level piezoelectric transducer in a simply supported beam structure under a traffic load provided by a third embodiment of the present disclosure;

FIG. 7 is a schematic diagram of a sectional structure of the piezoelectric device based on the watt-level piezoelectric transducer in a simply supported beam structure under a traffic load provided in FIG. 6; and

FIG. 8 is a structural schematic diagram of a piezoelectric transducer of the piezoelectric device based on the watt-level piezoelectric transducer in a simply supported beam structure under a traffic load provided in FIG. 6.

### DETAILED DESCRIPTION OF THE EMBODIMENTS

The technical solutions in embodiments of the present disclosure will be clearly and completely described below with reference to the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

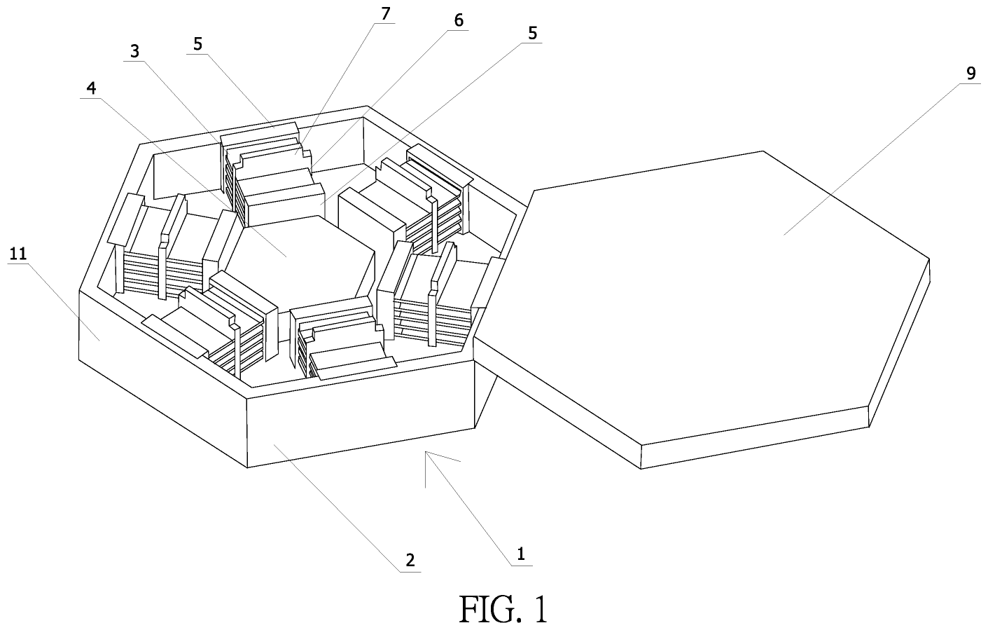

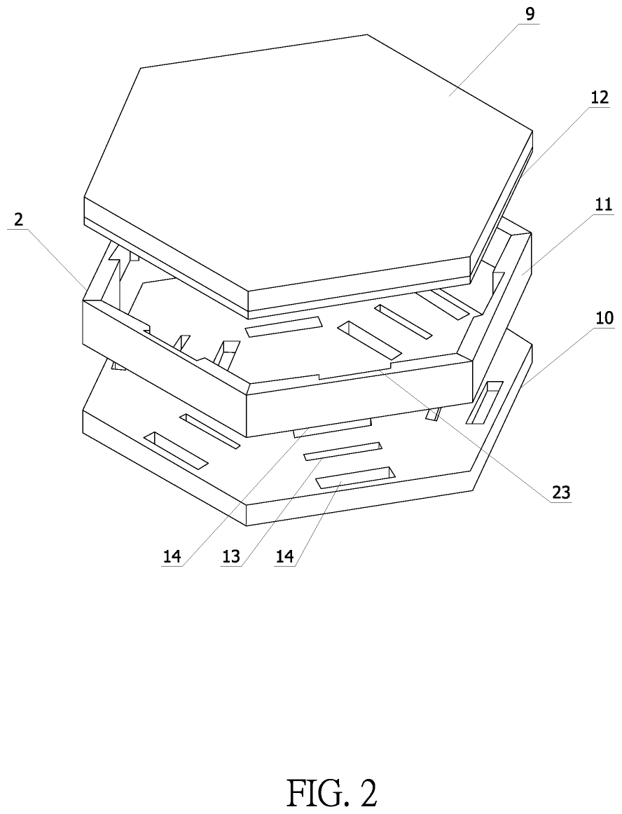

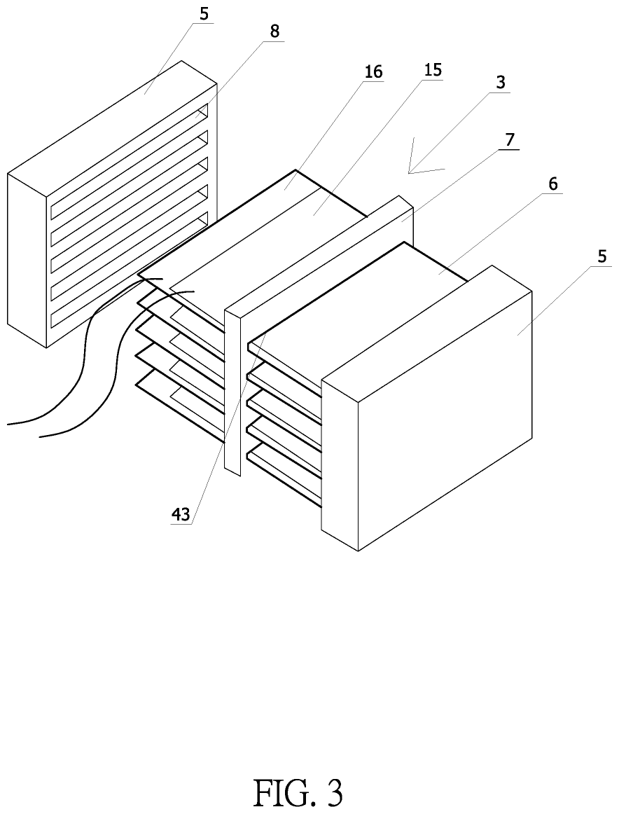

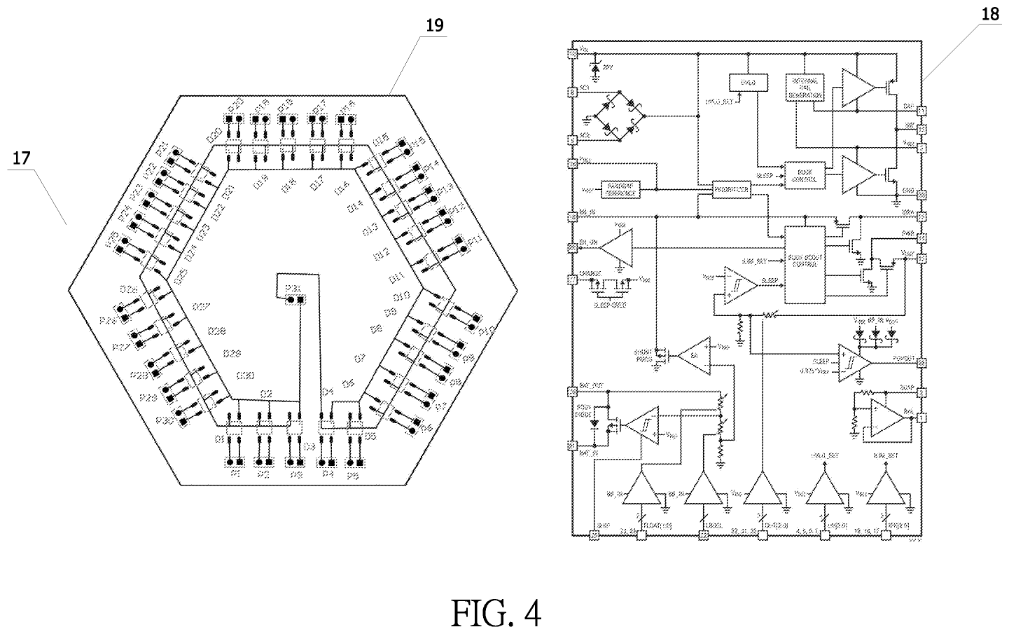

With reference to FIGS. 1-4, a first embodiment of the present disclosure provides a watt-level piezoelectric transducer in a simply supported beam structure under a traffic load. The piezoelectric transducer includes a piezoelectric transducer body 1, the piezoelectric transducer body 1 including a housing 2, a plurality of piezoelectric beam units 3 and an energy collection unit 4. The piezoelectric beam units 3 and the energy collection unit 4 are arranged in the housing, and the piezoelectric beam units 3 are electrically connected to the energy collection unit 4 by means of wires. The energy collection unit 4 is arranged in a middle of an inner cavity of the housing, and the plurality of piezoelectric beam units 3 are evenly distributed around the energy collection unit.

The piezoelectric beam unit 3 includes a beam support component, a plurality of piezoelectric plate components 6 and a metal stress transmission plate 7. The metal stress transmission plate 7 is carved from an aluminum alloy plate. The beam support component includes two support members 5 oppositely arranged, the support members 5 are made of fiber-reinforced nylon, and the support members 5 are in a simply supported beam structure. The metal stress transmission plate 7 is vertically arranged within a beam span between the two support members 5 oppositely arranged, the plurality of piezoelectric plate components 6 sequentially penetrate the metal stress transmission plate 7, two ends of each of the plurality of piezoelectric plate components 6 are transversely inserted between the two support members 5 in turn, and the plurality of piezoelectric plate components are arranged 6 in a simply supported manner. Gaps are provided between the simply supported piezoelectric plate components, such that each piezoelectric plate component has deformation space in an up-and-down direction, each piezoelectric plate component may be fully deformed by means of stress transmission of the metal stress transmission plate 7 to generate maximum power. Compared with the traditional piezoelectric device, the piezoelectric transducer may output more power with high electric energy. A plurality of evenly distributed bearing recesses 8 are cut on a side wall of each support member 5, a side wall of the metal stress transmission plate 7 is provided with a plurality of slots 43 corresponding to the plurality of bearing recesses, and the piezoelectric plate component 6 sequentially penetrates the slots with two ends inserted into the bearing recesses 8. When the two ends of the piezoelectric plate component 6 are inserted into the bearing recesses 8, displacement space is left between the bearing recesses 8 and the piezoelectric plate component 6, and the displacement space allows the piezoelectric plate component 6 to move in the bearing recesses 8. The displacement space provides deformation space for the piezoelectric plate component, and the piezoelectric plate component 6 may deform to the maximum extent for generating power in the bearing recess. When a load is transmitted to the piezoelectric plate component, the metal stress transmission plate sequentially transmits the load to each piezoelectric plate component layer by layer, and each piezoelectric plate component deforms to the maximum extent, and the piezoelectric plate component converts mechanical energy into electrical energy to generate maximum power, and electrical energy is transmitted to the energy collection unit.

The housing 2 includes an upper cover plate 9, a lower bottom plate 10 and side walls 11, the side walls 11 are composed of segmented side walls, and the side walls 11 are respectively fixed on outer sides of the lower bottom plate. The housing is made of fiber-reinforced nylon material, the housing 2 is carved by a CNC machine tool, and the lower bottom plate 10 and the side walls 11 of the housing are spliced together and fixed with epoxy resin glue. A bottom of the upper cover plate 9 is provided with a rubber buffer layer 12, the rubber buffer layer 12 is in contact with the piezoelectric plate component 6, and after being stressed, the rubber buffer layer may make the piezoelectric plate component 6 be pressed to the maximum extent. A plurality of recess groups adapted to the piezoelectric beam units are cut in the lower bottom plate 10, the recess group includes a stress transmission plate recess 13 and two support member recesses 14, and inner walls of that side walls are provided with slots 23 which correspond to and are adapted to the piezoelectric beam units. When the piezoelectric beam units 3 are placed into the housing, the support members 5 at outer sides of the piezoelectric beam units are inserted into the slots 23, bottoms of the support members 5 are stuck in corresponding support member recesses 14, and the metal stress transmission plates 7 are placed in corresponding stress transmission plate recesses 13.

The piezoelectric plate component 6 is composed of piezoelectric ceramic 15 and a stainless steel substrate 16, the piezoelectric ceramic 15 is fixed on the stainless steel substrate 16, the piezoelectric ceramic 15 and stainless steel substrate 16 are welded on one end of the wire, and the other end of the wire is connected to the energy collection unit 4.

The energy collection unit 4 includes a rectification unit 17 and an integrated circuit 18, the rectification unit 17 is a circuit board with a rectifier bridge 19, the plurality of piezoelectric plate components 6 are connected to the rectifier bridge 19 on the circuit board by means of wires respectively, the circuit board is a parallel circuit, the integrated circuit 18 is an energy management chip, and the energy management chip is connected to the circuit board by means of a wire.

The integrated transducer is connected to an external resistance box, and a fatigue testing machine is operated to change loading conditions and matching impedance. An output voltage U and an output current I of the transducer are read by an oscilloscope, and maximum output power is calculated and compared in the formula

$$P = \frac{{U}^{2}}{{R}_{0}} .$$

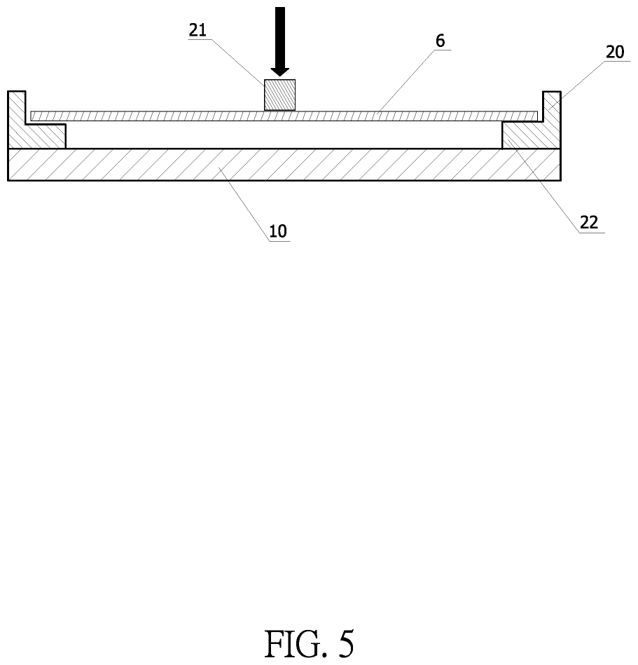

With reference to FIG. 5, a second embodiment of the present disclosure provides a watt-level piezoelectric transducer in a simply supported beam structure under a traffic load. The piezoelectric transducer includes a piezoelectric transducer body, a piezoelectric plate component 6, a simply supported bearing 20, a lower bottom plate 10 and a stress transmission rod 21, where the simply supported bearing 20 is fixed on the lower bottom plate 10, a support flange 22 is arranged in the simply supported bearing, and the piezoelectric plate component 6 is arranged on the support flange 22 to be simply supported, and the stress transmission rod 21 is fixed on the piezoelectric plate component 6. A load acts on the piezoelectric plate component 6 through the stress transmission rod 21, and the piezoelectric plate component is stressed to be deformed to generate power. The periphery of the piezoelectric plate component 6 is fixed on the support flange 22, and a bottom of an inner cavity of the simply supported bearing has space for the piezoelectric plate component to deform, such that the piezoelectric plate deforms to a larger extent to generate maximum power.

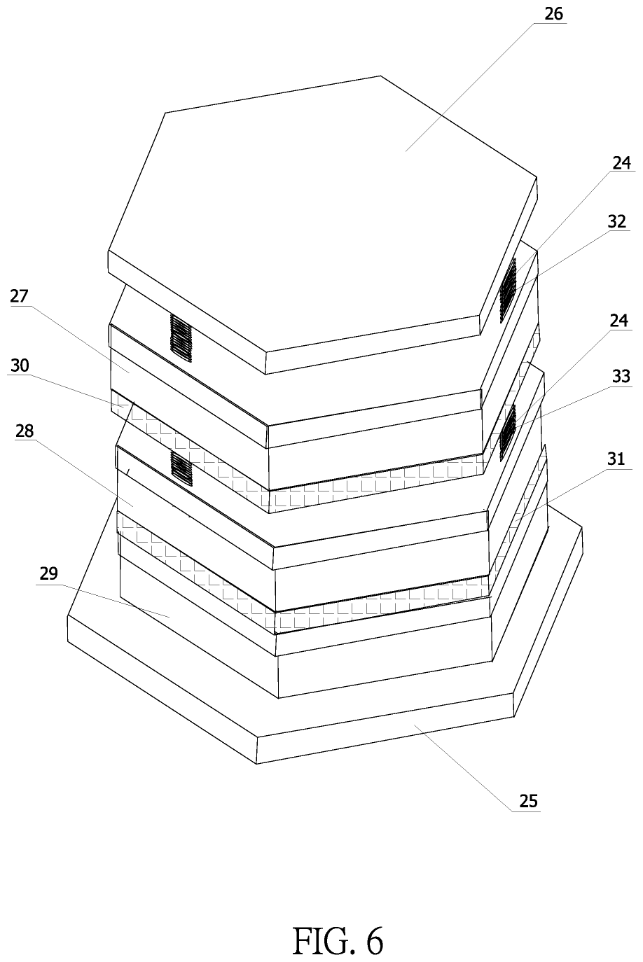

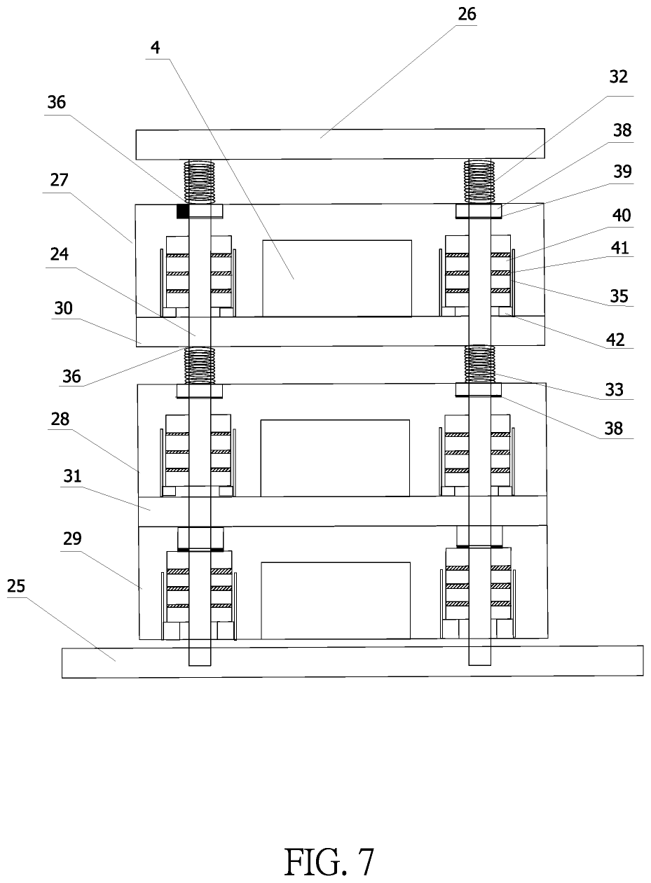

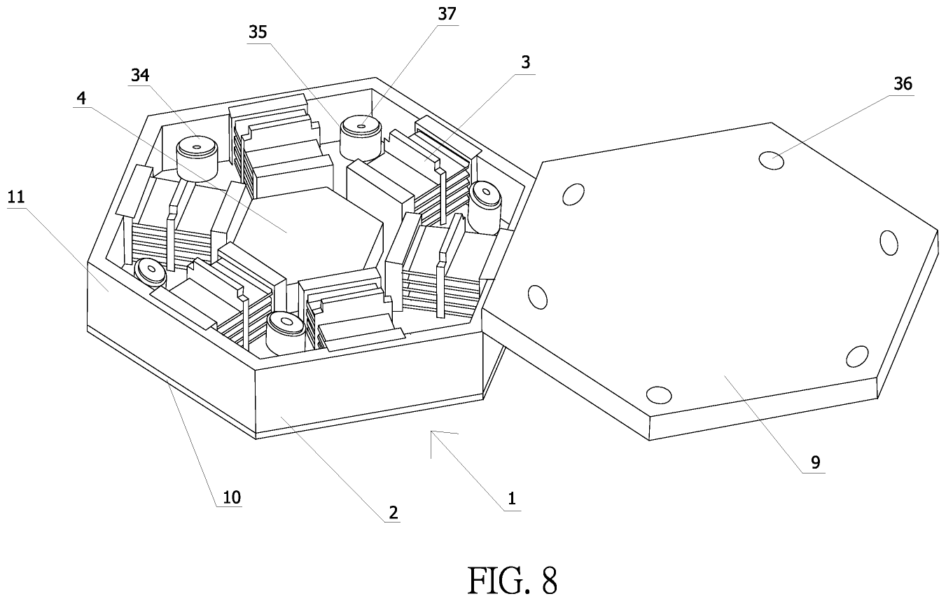

With reference to FIGS. 6-8, a third embodiment of the present disclosure provides a piezoelectric device based on the watt-level piezoelectric transducer in a simply supported beam structure under a traffic load, and the piezoelectric device is based on the piezoelectric transducer in the first embodiment.

The piezoelectric device includes a plurality of piezoelectric transducers 1, where the plurality of piezoelectric transducers are vertically arranged and connected and mounted by means of stress transmission devices. The stress transmission device includes at least two stress transmission rods 24, a bottom plate 25 and an upper loading plate 26. The stress transmission rods 24 sequentially penetrate the plurality of piezoelectric transducers 1, bottoms of the stress transmission rods 24 penetrate out of a bottom piezoelectric transducer to be connected to the bottom plate 25, tops of the stress transmission rods 24 extend out of a top piezoelectric transducer to be fixed on the upper loading plate 26, and a middle loading plate is arranged between adjacent piezoelectric transducers.

Three piezoelectric transducers, namely the top piezoelectric transducer 27, a middle piezoelectric transducer 28 and the bottom piezoelectric transducer 29, are preferably arranged. The middle loading plate includes an intermediate loading plate 30 and a lower loading plate 31, and the intermediate loading plate 30 is arranged between the top piezoelectric transducer 27 and the middle piezoelectric transducer 28, and the lower loading plate 31 is arranged between the middle piezoelectric transducer 28 and the bottom piezoelectric transducer 29. A plurality of first elastic devices 32 are arranged between the upper loading plate 26 and an upper cover plate 9 of a housing of the top piezoelectric transducer 27, and the first elastic devices 32 sleeve the stress transmission rods 24 respectively. An upper end of the intermediate loading plate 30 abuts against a bottom of a lower bottom plate of the housing of the top piezoelectric transducer, a plurality of second elastic devices 33 are arranged between a lower end of the intermediate loading plate 30 and an upper cover plate of a housing of the middle piezoelectric transducer 28, and the second elastic devices 33 sleeve the stress transmission rods respectively. An upper end face of the lower loading plate 31 abuts against a bottom of a lower bottom plate of the housing of the middle piezoelectric transducer, and a lower end face of the lower loading plate 31 abuts against a top of an upper cover plate of a housing of the bottom piezoelectric transducer. The first elastic device 32 is longer than the second elastic device 33. A distance between the loading plate and the piezoelectric transducer is set by the first elastic devices 32 and the second elastic devices 33. A distance between the upper loading plate 26 and the top piezoelectric transducer 27 is the longest followed by a distance between the intermediate loading plate 30 and the middle piezoelectric transducer 28, and the lower loading plate 31 abuts against a surface of the bottom piezoelectric transducer 29. When the vehicle load is transmitted to the upper loading plate 26, stress of the upper loading plate 26 is transmitted downwards by means of the stress transmission rod 21. Because there are gaps between the upper loading plate 26 and the top piezoelectric transducer 27 and between the intermediate loading plate 30 and the middle piezoelectric transducer 28, the upper loading plate 26 may not directly transmit the stress directly to the top piezoelectric transducer 27, but first transmits the stress to the lower loading plate 31 by means of the stress transmission rod 21, and exerts the stress to the bottom piezoelectric transducer 29 by means of the lower loading plate 31. The piezoelectric plate component in the bottom piezoelectric transducer is stressed and deformed to generate power which is transmitted to the energy collection unit by means of a wire. The stress transmission rod 21 first drives the lower loading plate 31 to transmit stress downwards, then the intermediate loading plate 30 presses the second elastic device 33 down, the intermediate loading plate 30 exerts stress on the middle piezoelectric transducer 28, and the piezoelectric plate component 6 in the middle piezoelectric transducer 28 is stressed and deformed to generate power. Finally, the upper loading plate 26 presses the first elastic device 32 down, the upper loading plate 26 exerts pressure on the top piezoelectric transducer 27, and the piezoelectric plate component in the top piezoelectric transducer 27 is stressed and deformed to generate power. The first elastic device 32 and the second elastic device 33 are preferably springs. Because the first elastic device 32 is longer than the second elastic device 33, the intermediate loading plate exerts pressure on corresponding piezoelectric transducers before the upper loading plate exerts pressure on corresponding piezoelectric transducers. The first elastic device 32 and the second elastic device 33 are arranged, such that the stress transmission rod 24 first transmits the stress to the bottom piezoelectric transducer 29, then to the middle piezoelectric transducer, and finally to the top piezoelectric transducer 27, thus achieving transmission of the vehicle load to the piezoelectric transducer of each layer and effective transmission of stress. If the vehicle load is directly transmitted to the top piezoelectric transducer, the middle piezoelectric transducer and the bottom piezoelectric transducer may receive a less load, and therefore generate less power due to insufficient effective deformation. A load generated by the vehicle in an instant is large, but may not be fully utilized by the piezoelectric transducer of single layer, and most of the load is wasted. By vertically arranging multi-layer piezoelectric transducers, the vehicle load is fully utilized, and the piezoelectric transducer of each layer may be deformed to generate power.

A plurality of annular piezoelectric components 34 are arranged in an inner cavity of a housing of each piezoelectric transducer, and the annular piezoelectric component is arranged at a gap between adjacent piezoelectric plate components 6, and the number of annular piezoelectric components is same to that of the stress transmission rods. The lower bottom plate of the housing is provided with an accommodation recess 35 for accommodating the annular piezoelectric component, and the annular piezoelectric component 34 is accommodated in the accommodation recess 35. The lower bottom plate and the upper cover plate of an inner cavity of the housing of the top piezoelectric transducer, the lower bottom plate and the upper cover plate of an inner cavity of the housing of the middle piezoelectric transducer and a lower bottom plate and the upper cover plate of an inner cavity of the housing of the bottom piezoelectric transducer are all provided with via holes 36 corresponding to the stress transmission rod, the via hole of the lower bottom plate is located at a bottom of the accommodation recess, and a middle via hole 37 of the annular piezoelectric component corresponds to and is in communication with the via hole of the lower bottom plate. The stress transmission rod 21 penetrates the piezoelectric transducer from the via hole of an upper cover plate of the housing of the piezoelectric transducer into the inner cavity of the housing, penetrates the middle via hole 37 of the annular piezoelectric component, and then out of the via hole of a lower bottom plate of the housing of the piezoelectric transducer.

Portions, located in the inner cavity of the housing of the piezoelectric transducer, of the stress transmission rod 24 are each provided with a stress transmission block 38, the stress transmission block 38 is located above the annular piezoelectric component 34, and an end, facing the annular piezoelectric component, of the stress transmission block is provided with a rubber cushion 39. Under the condition of being unstressed, the stress transmission block 38 always abuts against an inner surface of the upper cover plate to limit the stress transmission rod. Under the condition of being stressed, the stress transmission block 38 transmits, under stress, stress to the annular piezoelectric component. A distance between a stress transmission block in the top piezoelectric transducer and the annular piezoelectric component is the same as that between the upper loading plate and the top piezoelectric transducer, a distance between a stress transmission block in the middle piezoelectric transducer and the annular piezoelectric component is the same as that between the intermediate loading plate and the middle piezoelectric transducer, and a stress transmission block in the bottom piezoelectric transducer abuts on an upper surface of the annular piezoelectric component.

The annular piezoelectric component is composed of a plurality of annular piezoelectric plates 40, the plurality of annular piezoelectric plates are sequentially distributed vertically, a silica gel gasket 41 is arranged between adjacent annular piezoelectric plates, and the annular piezoelectric plates 40 are connected to the energy collection unit 4 by means of wires respectively. The annular piezoelectric plate is composed of an annular metal substrate and annular piezoelectric ceramic. A bottom edge of the accommodation recess 35 is provided with a border 42, the annular piezoelectric component is placed on the border 42 of the accommodation recess, and deformation space is left between a bottom end of the annular piezoelectric component and the bottom of the accommodation recess. The annular piezoelectric component may also be designed to be inserted into the accommodation recess at one time, and there are deformation spaces between every two adjacent annular piezoelectric plates. Through arrangement of the annular piezoelectric component, empty space in the housing of the piezoelectric transducer is fully utilized, and the vehicle load is fully utilized.

What is described above is merely the preferred implementation manner of the present disclosure, the protection scope of the present disclosure is not limited to the above embodiments, but all technical solutions under the idea of the present disclosure shall fall within the protection scope of the present disclosure. It shall be noted that several improvements and polishing made by those of ordinary skill in the art on the premise without deviating from a principle of the present disclosure shall be integrated as falling within the protection scope of the present disclosure.

What is claimed is:

1. A watt-level piezoelectric transducer in a simply supported beam structure under a traffic load, comprising a piezoelectric transducer body, the piezoelectric transducer body comprising a housing, a plurality of piezoelectric beam units and an energy collection unit, wherein the piezoelectric beam units and the energy collection unit are arranged in the housing, and the piezoelectric beam units are electrically connected to the energy collection unit by means of wires; each piezoelectric beam unit comprises a beam support component, a plurality of piezoelectric plate components and a metal stress transmission plate, wherein the beam support component comprises two support members oppositely arranged, the support members are in a simply supported beam structure, and the metal stress transmission plate is vertically arranged within a beam span between the two support members oppositely arranged; and the plurality of piezoelectric plate components sequentially penetrate the metal stress transmission plate, two ends of each of the plurality of piezoelectric plate components are transversely inserted between the two support members in turn, and the plurality of piezoelectric plate components are arranged in a simply supported manner.

2. The watt-level piezoelectric transducer in a simply supported beam structure under a traffic load according to claim 1, wherein the housing comprises an upper cover plate, a lower bottom plate and side walls, the side walls are composed of segmented side walls, and the side walls are respectively fixed on outer sides of the lower bottom plate; a bottom of the upper cover plate is provided with a rubber buffer layer, a plurality of recess groups adapted to the piezoelectric beam units are cut in the lower bottom plate, the recess group comprising a stress transmission plate recess and two support member recesses, and inner walls of that side walls are provided with slots which correspond to and are adapted to the support members of the piezoelectric beam units; and when the piezoelectric beam units are placed into the housing, the support members at outer sides of the piezoelectric beam units are inserted into the slots, bottoms of the support members are placed in corresponding support member recesses, and the metal stress transmission plates are placed in corresponding stress transmission plate recesses.

3. The watt-level piezoelectric transducer in a simply supported beam structure under a traffic load according to claim 2, wherein the piezoelectric plate component is composed of piezoelectric ceramic and a stainless steel substrate, the piezoelectric ceramic is fixed on the stainless steel substrate, the piezoelectric ceramic and stainless steel substrate are welded on one end of the wire, and the other end of the wire is connected to the energy collection unit.

4. The watt-level piezoelectric transducer in a simply supported beam structure under a traffic load according to claim 3, wherein the energy collection unit comprises a rectification unit and an integrated circuit, the rectification unit is a circuit board with a rectifier bridge, the plurality of piezoelectric plate components are connected to the rectifier bridge on the circuit board by means of wires respectively, the integrated circuit is an energy management chip, and the energy management chip is connected to the circuit board by means of a wire.

5. The watt-level piezoelectric transducer in a simply supported beam structure under a traffic load according to claim 1, wherein a plurality of evenly distributed bearing recesses are cut on a side wall of each support member, the bearing recesses of the two support members are oppositely provided, the two ends of each piezoelectric plate component are inserted into the bearing recesses respectively, when the two ends of each piezoelectric plate component are inserted into the bearing recesses, displacement space is left between the bearing recesses and the piezoelectric plate component, and the displacement space allows the piezoelectric plate component to move in the bearing recesses.

6. A watt-level piezoelectric transducer in a simply supported beam structure under a traffic load, comprising a piezoelectric transducer body, a piezoelectric plate component, a simply supported bearing, a lower bottom plate and a stress transmission rod, wherein the simply supported bearing is fixed on the lower bottom plate, a support flange is arranged in the simply supported bearing, and the piezoelectric plate component is arranged on the support flange, and the stress transmission rod is fixed on the piezoelectric plate component.

7. A piezoelectric device based on the watt-level piezoelectric transducer in a simply supported beam structure under a traffic load according to claim 1, comprising a plurality of piezoelectric transducers, wherein the plurality of piezoelectric transducers are vertically arranged and connected and mounted by means of stress transmission devices; a plurality of annular piezoelectric components are arranged in an inner cavity of a housing of each piezoelectric transducer, and the annular piezoelectric component is arranged at a gap between adjacent piezoelectric plate components; the stress transmission device comprises at least two stress transmission rods, a bottom plate and an upper loading plate, wherein the stress transmission rods sequentially penetrate the plurality of piezoelectric transducers, bottoms of the stress transmission rods penetrate out of a bottom piezoelectric transducer to be connected to the bottom plate, and tops of the stress transmission rods extend out of a top piezoelectric transducer to be fixed on the upper loading plate; and a middle loading plate is arranged between adjacent piezoelectric transducers, and the stress transmission rod penetrates the piezoelectric transducer from an upper cover plate of the housing of the piezoelectric transducer into the inner cavity of the housing, penetrates a middle of the annular piezoelectric component, and then out of a lower bottom plate of the housing of the piezoelectric transducer.

8. The piezoelectric device based on the watt-level piezoelectric transducer in a simply supported beam structure under a traffic load according to claim 7, wherein three piezoelectric transducers, namely the top piezoelectric transducer, a middle piezoelectric transducer and the bottom piezoelectric transducer, are preferably arranged; the middle loading plate comprises an intermediate loading plate and a lower loading plate, and the intermediate loading plate is arranged between the top piezoelectric transducer and the middle piezoelectric transducer, and the lower loading plate is arranged between the middle piezoelectric transducer and the bottom piezoelectric transducer; a plurality of first elastic devices are arranged between the upper loading plate and an upper cover plate of a housing of the top piezoelectric transducer, the first elastic devices sleeve the stress transmission rods respectively, an upper end of the intermediate loading plate abuts against a bottom of a lower bottom plate of the housing of the top piezoelectric transducer, a plurality of second elastic devices are arranged between a lower end of the intermediate loading plate and an upper cover plate of a housing of the middle piezoelectric transducer, and the second elastic devices sleeve the stress transmission rods respectively; and an upper end face of the lower loading plate abuts against a bottom of a lower bottom plate of the housing of the middle piezoelectric transducer, a lower end face of the lower loading plate abuts against a top of an upper cover plate of a housing of the bottom piezoelectric transducer, and the first elastic device is longer than the second elastic device.

9. The piezoelectric device based on the watt-level piezoelectric transducer in a simply supported beam structure under a traffic load according to claim 8, wherein the lower bottom plate and the upper cover plate of an inner cavity of the housing of the top piezoelectric transducer, the lower bottom plate and the upper cover plate of an inner cavity of the housing of the middle piezoelectric transducer and a lower bottom plate and the upper cover plate of an inner cavity of the housing of the bottom piezoelectric transducer are all provided with via holes corresponding to the stress transmission rod; the lower bottom plate of the housing is provided with an accommodation recess adapted to the annular piezoelectric component, the via hole of the lower bottom plate is located at a bottom of the accommodation recess, the annular piezoelectric component is placed in the accommodation recess, and a middle via hole of the annular piezoelectric component corresponds to and is in communication with the via hole of the lower bottom plate; portions, located in the inner cavity of the housing of the piezoelectric transducer, of the stress transmission rod are each provided with a stress transmission block, and the stress transmission block is located above the annular piezoelectric component; and under the condition of being unstressed, the stress transmission block always abuts against an inner surface of the upper cover plate and under the condition of being stressed, the stress transmission block transmits, under stress, stress to the annular piezoelectric component.

10. The piezoelectric device based on the watt-level piezoelectric transducer in a simply supported beam structure under a traffic load according to claim 7, wherein the annular piezoelectric component is composed of a plurality of annular piezoelectric plates; the plurality of annular piezoelectric plates are sequentially stacked, a silica gel gasket is arranged between adjacent annular piezoelectric plates, and the annular piezoelectric plates are connected to the energy collection unit by means of wires respectively; a bottom edge of the accommodation recess is provided with a border, the annular piezoelectric component is placed on the border of the accommodation recess, and gap space is left between a bottom end of the annular piezoelectric component and the bottom of the accommodation recess; and an end, facing the annular piezoelectric component, of the stress transmission block is provided with a rubber cushion.
